(19) United States
(12) Patent Application Publication
(10) Pub. No.: US 2012/0164353 A1
(43) Pub. Date: Jun. 28, 2012

(54) PLASMA ENHANCED CHEMICAL VAPOR DEPOSITION APPARATUS

(76) Inventor: John Madocks, Tucson, AZ (US)

(21) Appl. No.: 13/394,305

(22) PCT Filed: Sep. 7, 2010
(86) PCT No.: PCT/US2010/047994

§ 371 Date: Mar. 5, 2012

Related U.S. Application Data
(60) Provisional application No. 61/275,930, filed on Sep. 5, 2009.

(51) Int. Cl. C23C 16/50; C23C 16/511; C23C 16/06

(52) U.S. Cl. 427/576; 118/723 R; 427/569; 118/723 MW

(57) ABSTRACT

PECVD apparatus for depositing material onto a moving substrate is provided comprising a process chamber, a precursor gas inlet to the process chamber, a pumped outlet, and a plasma source disposed within the process chamber. The plasma source produces one or more negative glow regions and one or more positive columns. At least one positive column is disposed toward the substrate. The plasma source and precursor gas inlet are disposed relative to each other and the substrate such that the precursor gas is injected into the positive column adjacent the substrate. Apparatus is provided to channel the precursor gas into the positive column away from the negative glow region.

### CROSS-REFERENCE TO RELATED APPLICATION

This application claims priority of U.S. Provisional Patent Application Ser. No. 61/275,930, filed Sep. 5, 2009, which is incorporated herein by reference.

### FIELD OF THE INVENTION

The present invention relates to plasma enhanced chemical vapor deposition (PECVD) apparatus and processes.

### BACKGROUND OF THE INVENTION

Plasma enhanced chemical vapor deposition (PECVD) is a process used to deposit thin films from a gas state (vapor) precursor to a solid state coating on a substrate. Chemical reactions are involved in the process of reacting the precursor in a deposition chamber with a plasma. In conventional CVD, heating is usually applied to promote precursor decomposition reactions. PECVD deposition on a substrate can be accomplished at ambient or relatively low temperatures compared with traditional thermal chemical vapor deposition (CVD). PECVD differs from sputtering in that the material forming the plasma electrode does not form a significant amount of the deposited film in a PECVD process.

PECVD has not been more widely used owing to the coating not just on the substrate where it is wanted, but also on other surfaces including critical electrode surfaces of the plasma source. If the coating is non-conducting, the operating characteristics of the plasma source become an operational dynamic that inhibits coating uniformity in commercial production. For instance, with an insulating film such as SiO₂, electrode coating can cause arcing or the complete cessation of source operation after typically about 4 to 8 hours of continuous operation thereby requiring production to be interrupted for disassembly and cleaning.

In PECVD, the breakdown of precursor gases occurs in the presence of plasma. If the electrodes driving plasma generation are exposed to the precursor gas, a significant percentage of deposition occurs on the electrode. This is especially true when sputter magnetron type plasma sources are used and the precursor is exposed to the intense racetrack negative glow. Coating buildup on the magnetron electrode(s) causes severe process difficulties: The electrical circuit impedance varies with the buildup affecting process stability and the efficiency of the process, including the deposition rate and materials usage, is reduced to the degree of electrode coating.

In prior art PECVD apparatus, while useful coatings may be deposited on the substrate, the source is quickly coated causing process drift and arcing. In semiconductor batch applications, an etch process is run after set intervals to clean the exposed electrode(s). In continuous processes, such as roll-to-roll web or in-line coating systems, a PECVD process must run for many tens of hours without stopping. In these applications an etch cleaning cycle is not practical. There exists a need to maintain a continuous performance PECVD process over a timescale amenable to mass production.

There also exists a need for a plasma source capable of such operation and deposition onto a wide substrate of greater than 1 meter linear uniformity.

### SUMMARY OF THE INVENTION

In the embodiments of the invention, coating buildup on the magnetron is minimized and long PECVD coating runs are made possible. The configurations of the embodiments of the invention PECVD deposition on large area substrates are particularly benefited and long, continuous PECVD processes are enabled.

In accordance with the principles of the invention, a plasma enhanced chemical vapor deposition apparatus for depositing material onto a substrate surface has a process chamber; and at least one plasma source disposed within the process chamber. The plasma source produces a negative glow region and a positive column. The at least one plasma source is disposed in proximity to the substrate surface such that the positive column is directed to the substrate surface. The PECVD apparatus further comprises at least one inlet to inject a precursor gas into the process chamber to interact with the positive column to deposit material onto the substrate; and at least one outlet for providing a pumped exit for gas in the chamber. The at least one inlet, at least one outlet, and the at least one plasma source are positioned in relationship to the substrate surface and to each other such that substantially all the precursor gas injected into the process chamber from the at least one inlet flows into the positive column adjacent the substrate surface.

In embodiments of the invention, apparatus is provided within the process chamber to channel or direct the precursor gas to flow into the positive column. In certain embodiments of the invention the apparatus has a shield to channel precursor gas into the positive column.

In some embodiments of the invention an inlet manifold provides the at least one or more inlets.

In some embodiments of the invention the apparatus is disposed adjacent to the inlet manifold to channel the precursor gas into the positive column adjacent the substrate surface.

In various embodiments of the invention, the substrate is a moving substrate. In certain embodiments, the substrate is a flexible substrate.

In specific embodiments the at least one plasma source includes a rotary plasma; at least one dual rotary magnetron plasma source; a planar magnetron; or at least one dual planar magnetron plasma source.

Embodiments include at least a second inlet to provide reactive gas to the at least one plasma source.

A process for plasma enhanced chemical vapor deposition coating of material onto a surface of a substrate is provided that includes provision of a process chamber in which at least one plasma is disposed. Each of said at least one plasma producing a negative glow region adjacent to a plasma and encompassed within a positive column projecting toward the substrate surface. A chemical vapor deposition precursor gas is injected into the process chamber to interact substantially only with said positive column and to deposit the material by plasma enhanced chemical vapor deposition coating onto the surface of the substrate. Interaction of the gas with said negative glow region is inhibited thereby keeping the plasma source free of fouling material deposits.

In accordance with embodiments, the method includes providing apparatus within the chamber to channel the precursor gas into the positive column. Certain embodiments include utilizing dual magnetron plasma sources. The process is applicable to flexible and self supporting substrates. Deposition can proceed in excess of 100 continuous hours owing the lack of magnetron fouling by the material, especially with the material is an electrically insulating material such as a metal oxide.

### BRIEF DESCRIPTION OF THE DRAWINGS

The invention will be better understood from a reading of the following detailed description of embodiments of the invention in which like reference designators are utilized to identify like elements, and in which the relative sizes and positions of various elements are exemplary only and are not intended to be limiting in any way, and in which:

FIG. 1 is a cross-sectional schematic view of a magnetron plasma source and the generalized shape and relative dimensions of regions within the discharge so produced during operation;

FIG. 2 is a cross-sectional schematic view of PECVD magnetron plasma sources for operation as in an inventive apparatus;

FIG. 3 is a cross-sectional schematic view of electrically coupled rotary magnetron plasma source for operation as an inventive PECVD apparatus;

FIG. 4 is a cross-sectional schematic view of an inventive roll coater PECVD embodiment in operation; and

FIGS. 5A and 5B are perspective and cross-sectional views of another inventive PECVD apparatus.

### DETAILED DESCRIPTION OF THE PREFERRED EMBODIMENTS

The present invention has utility in the plasma enhanced chemical vapor deposition (PECVD) of volatile precursors onto a substrate. The present invention largely overcomes the prior art problem of electrically insulating coatings building up on deposition electrodes by preferentially injecting precursor gas into the positive column and adjacent to a deposition substrate, such that the negative glow region is exposed to a limited amount of precursor so as to limit coating growth onto the magnetron target proximal to the negative glow region.

In each of the embodiments shown and described hereinafter, the process chamber, magnetron plasma source, precursor gas inlet, and pump outlet are configured to provide a flow path or flow paths that preferentially channel injected CVD precursor gas into the plasma source positive column adjacent the substrate such that precursor gas interaction with the lobular areas defining the negative glow regions is disfavored and substantially eliminated. The various embodiments described herein are representative of configurations and it will be appreciated by those skilled in the art that the invention is not limited in scope to the particular configurations shown and described.

For purposes of clarity, various structural features of the process chambers, plasma sources and substrate transport apparatus are not shown. In addition, various shield and channel structural apparatus and configurations are not shown. The specific structures and configurations likewise are not to be considered as limiting the scope of the invention.

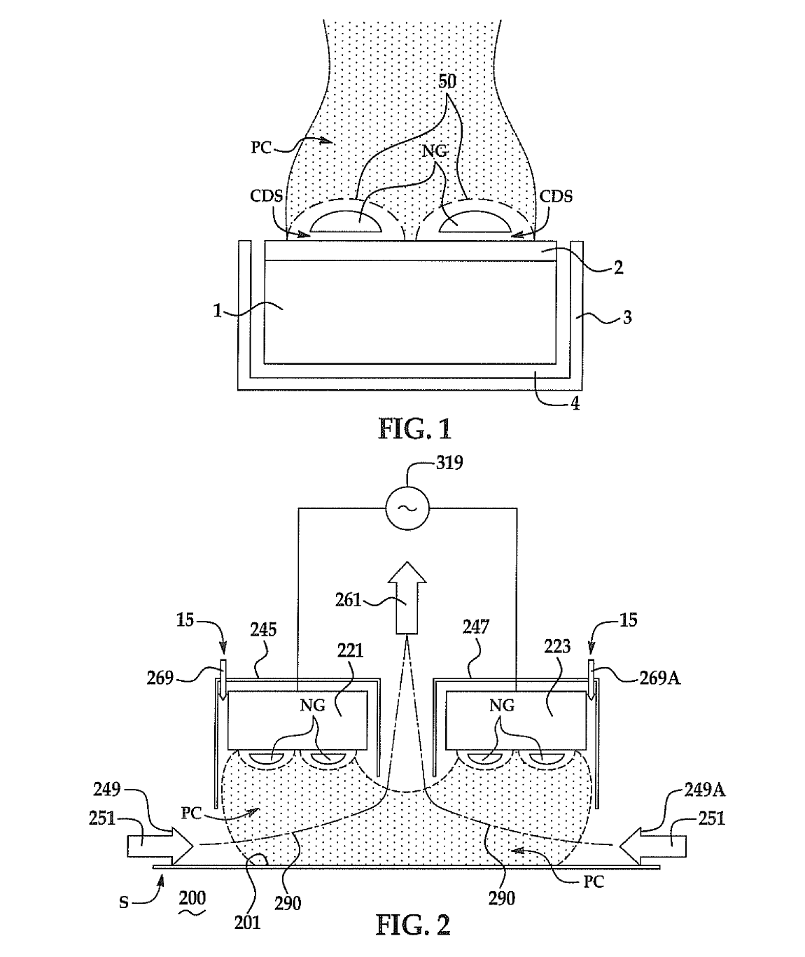

FIG. 1 illustrates a planar magnetron 1 operating as the plasma source. Planar magnetron 1 is shown in cross section and is illustrated as a planar magnetron, but as will be understood by those skilled in the art, the principles of the invention apply to other known types of plasma sources illustratively including different types of magnetron cathodes. It is not intended that the descriptions provided herein are limited to any specific magnetron construction or structure. A magnetron plasma source as depicted and operative in the present invention is well suited to having a linear dimension orthogonal to the plane of the cross-section of greater than 1 meter, greater than 2 meters, greater than 3 meters, and greater than 4 meters. While most conventional substrates, whether a finite length rigid sheet or an elongated ribbon sheet, have a width of less than 4 meters, sheets of widths exceeding 4 meters can be contemplated. An inventive apparatus is readily constructed with a linear extent to provide controlled deposition across sheets of a width greater than 4 meters.

A magnetron plasma discharge may be described by three regions: a cathode dark space (CDS), a negative glow region (NG), and a positive column (PC). Planar magnetron 1 has an exposed electrode surface termed the target 2 and can be surrounded by a grounded shield 3. Between the high voltage magnetron 1 and shield 3 is dark space 4. Dark space 4 exists to prevent a plasma from lighting on the sides or back of magnetron 1 and also to prevent unwanted arcing. Magnetic field lines 50 contain negative glow NG adjacent to target 2. These designations are used throughout the following drawings. These regional designations are intended to have the common meaning and physical attributes, as understood by one of skill in the art to which the invention pertains.

In a conventional PECVD arrangement, CVD precursor gas introduced into a process chamber disperses at a high rate of speed, i.e., the speed of sound, throughout the chamber. The precursor gas interacts with the plasma to produce condensable constituents that deposit material onto nearby surfaces. In prior art PECVD systems and processes, the precursor gas was not directed into the positive column. Because the magnetron negative glow NG is the densest plasma, the precursor gas interacted strongly with the NG and material deposited onto the magnetron target.

FIG. 2 is a transverse cross-sectional view through an inventive PECVD apparatus, shown generally at 200 for depositing a coating onto the surface 201 of a substrate S. PECVD apparatus 200 resides in a vacuum chamber (not shown). Moving substrate surface 201 may be the surface of a rigid substrate, a flexible substrate, or a partially flexible substrate, the substrate S being a stackable sheet or an elongated ribbon sheet. A plasma source is provided that includes dual magnetron cathodes 221, 223 that are disposed within the chamber. As depicted, each magnetron 221, 223 is a planar magnetron that extends perpendicular to the plane of the drawing sheet to a length of up to 5 meters. Each magnetron 221, 223 produces lobular negative glow NG and a positive column PC. The positive column PC emanates from each negative glow NG and the two positive columns overlap to appear as one plasma region. A shield 245 is disposed around magnetron 221 and a shield 247 is disposed around magnetron 223. A non-condensing, inert or reactive gas 15 is supplied to magnetrons 221, 223 via a conduit or manifold 269 and 269A, respectively. By way of example, the inert gas may be argon or helium. The reactive gas may be oxygen, or nitrogen. Reactive gas is appreciated to be used in pure form or mixed with reactive gases that catalyze PECVD reactive and/or integrate into a resultant coating such as oxynitrides, or oxyfluorides in the case of oxygen and nitrogen bearing and fluorine bearing reactive gases, respectively. It is further appreciated that a reactive gas is diluted with an inert gas that is defined as being nonreactive under PECVD conditions being employed. Magnetrons 221, 223 are disposed such that the positive columns PC form a sheet adjacent substrate surface 201. CVD precursor gases 251 and 251A are injected into process chamber 200a at inlets 249 and 249A. A vacuum pumped outlet 261 is also provided to exhaust coating byproducts and excess reactive gas. Inlets 249 and 249′ are provided by an inlet manifold that is structured to provide a uniform gas flow over the entire length of the manifold. The precursor gases 251 and 251A are compositionally the same or different and optionally include varying amounts of inert buffer gas.

Magnetrons 221, 223 are connected on opposite sides of AC power supply 319. Power supply 319 is an alternating current power supply with an exemplary frequency range of between 20 kHz and 6000 kHz. Power supplies with higher or lower frequencies can also be used.

PECVD apparatus 200 is configured with positive columns PC disposed proximate substrate surface 201 such that precursor gas flow paths 290 from the precursor inlets 249 and 249A pass preferentially into positive columns PC adjacent to the substrate surface 201 to deposit material onto substrate surface 201. Magnetrons 221, 223 and inlets 249 and 249A disposed relative to each other and to substrate surface 201 to ensure that precursor gas 251 is injected into positive columns PC adjacent to the substrate surface 201. Upon contact with the plasma positive columns PC, the precursor gas 251 is broken apart and condensing molecular components form. These components land on nearby surfaces and form the PECVD coating. By positioning the precursor inlet 19 to be proximal to substrate s and distant from rotary magnetrons 30,31 negative glows NG, the condensable molecules preferentially deposit onto the substrate rather than the rotary magnetron electrode surface. By providing apparatus or shields 245, 247 and selectively positioning precursor gas inlets 249 and 249A and pumped outlet 261 with respect to apparatus or shields 245, 247 and magnetrons 221, 223, precursor flow paths 290 are defined such that precursor gas interaction with negative glow regions NG is significantly reduced if not substantially eliminated, thereby allowing PECVD apparatus 200 to operate for long periods of continuous operation in excess of 100 hours for oxide deposition without significant degradation. It is appreciated that alternate positions are provided for inlets 249, 249A, 269, 269A and outlet 261 to avoid coating deposition onto magnetrons 221 and 223. Illustrative of these positions include slotted or periodically apertured manifolds within PC perpendicular to the plane of the page in FIG. 2.

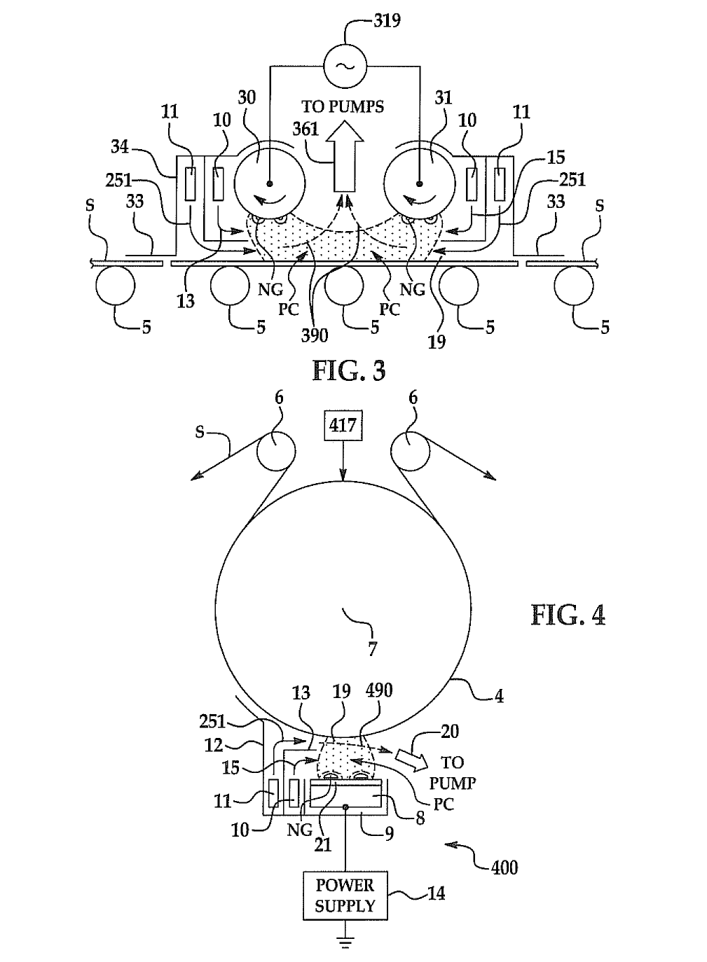

FIG. 3 is a transverse cross-sectional view through another inventive PECVD apparatus shown generally at 300. Like reference numerals used with respect to FIG. 3 have the meaning ascribed thereto with reference to the aforementioned figures and description of the invention. Apparatus 300 includes a vacuum chamber (not shown) through which a planar substrate S is conveyed to apply a PECVD coating. The substrate is transited within chamber via a conveyance system including driven rollers as is known in the art and shown generically at 5.

Dual rotary magnetrons 30, 31 are utilized in this embodiment as the plasma source. Each rotary magnetron 30, 31 extends perpendicular to the plane of the drawing sheet with a length and in a manner analogous to 221 and 223 per FIG. 2. The rotary magnetrons 30, 31 produce negative glow regions NG and overlapping positive columns PC as shown. An alternating current AC power supply 319 is provided for rotary magnetrons 30, 31. Rotary magnetrons 30, 31 are disposed such that the overlapping positive columns PC interact with substrate surface 301

Precursor gas distribution manifolds 11 are installed inside sheet metal conduits 34. The manifolds 10 and 11 each have a length that approximately corresponds to that of the magnetrons 30 and 31. Precursor gas 251, flowing from manifolds 11, is conducted into the PC adjacent to the substrate S by conduit 34 shield 13. Conduit shield 13 stops adjacent to the PC at opening 19. Shield 33 is close to substrate S and limits the flow of precursor gas 17 away from the PC. A reactive or inert gas manifold 10 is installed adjacent to rotary magnetrons 30 and 31. Reactive or inert gas flow 15 is directed to flow between the precursor gas and the magnetron 30, 31. Shield 13 helps to direct the flow of reactive or inert gas 15. Manifolds 11 and 10 are designed to provide theoretically uniform flow across the width of the manifold to promote uniform PECVD deposition on the substrate S.

The flow of precursor gas 251 and reactive or inert gas 15 flow into the PC is enhanced by the configuration of the vacuum pumping. By configuring the vacuum pumping opposite the gas manifolds as shown, the gases 15 and 251 are drawn into and through the PC before reaching the vacuum pumps. This increases the efficiency of precursor gas 251 and reactive or inert gas 15 utilization. The vacuum pumping 361 is configured to draw the gas out at a theoretically uniform rate over the entire length of the process area. It is appreciated that each of the rotary magnetrons 30 and 31 is independently replaced with a stationary planar magnetron 231 or 232 as detailed with respect to FIG. 2.

PECVD apparatus 300 is configured such that precursor gas 251 is injected into positive columns PC adjacent substrate surface 301 to interact with positive columns PC to deposit material onto substrate surface 301. Flow paths 390 are selected such that any unreacted CVD precursor gas, after the initial contact with the positive columns PC, 251 is inhibited from reacting the lobular negative glow regions NG. By providing shield 13 and selectively positioning precursor gas inlets 19 and pumped outlet 361 with respect to rotary magnetrons 30, 31, precursor gas interaction with negative glow regions NG is substantially eliminated, thereby allowing PECVD apparatus 300 to operate for long periods of continuous operation of at least 24 hours and in excess of 40 hours, 60 hours, 80 hours, and even 200 hours without significant degradation associated with CVD electrically insulating deposition of magnetron targets.

A roll coater or web coater is a special batch-type system that allows coating of a flexible material sheet (“web”) in the form of a roll. This type of system is typically used to coat polymer, paper and steel sheet materials. In these types of systems the material to be coated is unrolled, passed through a deposition zone, and re-rolled. Due to the long lengths of sheet material efficiently contained in rolled form, a deposition process to coat the entire roll can require long periods of time.

In the “web coating” process, a flexible substrate sheet is supplied from one roll, taken up by a second roll. The rolls may be located either in the vacuum, or outside with the web being passed through multiple, differentially pumped seals.

FIG. 4 illustrates the deposition portion roll or web coater type PECVD system apparatus 400. Like reference numerals used with respect to FIG. 4 have the meaning ascribed thereto with respect to the aforementioned figures and description. A flexible web substrate S is conveyed to and from drum 7 on idler rolls 6. Web substrate S is supported around drum 7 and is optionally cooled or heated by the drum 7. Web conveyance and temperature control are well known in the art and are depicted collectively at 417. PECVD apparatus 400 includes planar magnetron 8 positioned such that target 21 faces web substrate S and drum 7. Power supply 14 initiates and sustains a plasma on magnetron target 21. Power supply 14 may be a DC, pulsed DC, AC or RF type power supply. In operation, magnetron 8 plasma has negative glow, NC and positive column PC components. PECVD apparatus further includes precursor manifold 11 in sheet metal housing 12. Precursor gas 251 is directed to exit housing 12 adjacent to substrate S and the PC at opening 19. Shield 13 blocks precursor gas 251 from “seeing” magnetron target surface 21 before it encounters the PC. A second gas manifold 10 directs non-condensing reactive or inert gas 15 between the precursor gas inlet 19 and planar magnetron target 21. Both the precursor gas 251 remnants and reactive or inert gas 15 flow between the substrate S and magnetron 8 and then to the vacuum pumps (not shown). The flow to the pumps is depicted by arrow 20. In a PECVD process, precursor gas interacts upon contact with the PC and a coating 4 is made on substrate S. Because the substrate S is the most proximal surface to the precursor gas-plasma interaction, the substrate S receives the majority of the coating. The magnetron target 21 surface is relatively distant from the precursor gas inlet 19 and only receives a minimal amount of CVD deposition coating. If sufficiently small, the coating buildup on target 21 is removed by the NG sputter action on target 21 and target 21 thereby remains clean. This allows PECVD apparatus 400 to operate for long periods of continuous operation of at least 24 hours and in excess of 40 hours, 60 hours, 80 hours, 100 hours, and even 200 hours without significant degradation associated with CVD electrically insulating coating deposition of magnetron targets.

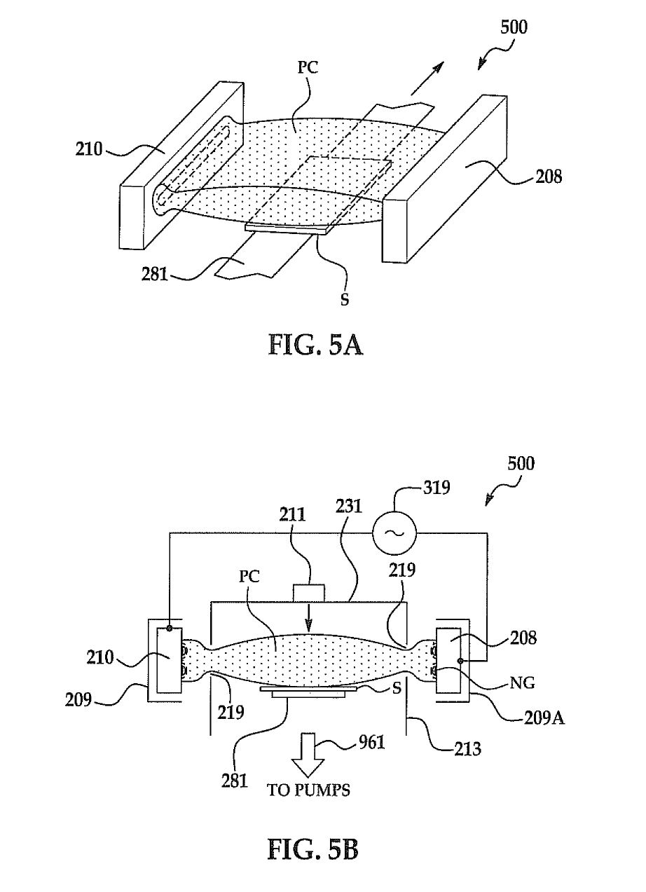

Turning now to FIGS. 5A and 5B, yet another embodiment of the invention is shown in which a PEVCD coating apparatus 500 deposits a coating on moving substrate S. Like reference numerals used with respect to FIG. 4 have the meaning ascribed thereto with respect to the aforementioned figures and description. Substrate S may be a rigid moving substrate, such as a substrate of glass or metal or a flexible substrate such as a polymer. Substrate S is transported or conveyed on belt 281 through positive column PC that is produced by a plasma source comprising magnetrons 208 and 210. Magnetrons 208 and 210 are preferably operated with matched deposition characteristic parameters.

In this embodiment, magnetrons 208 and 210 are positioned facing each other across substrate S. Magnetrons 208 and 210 are shown in a perspective view in FIG. 5A and a cross-section view in FIG. 5B. Each magnetron 208, 210 preferably includes a dark space shield 209, 209A, respectively.

Magnetrons 208 and 210 are each independently planar magnetrons with an unbalanced magnetic field configuration with the larger magnet on the outside of the racetrack. This is classically termed a Type II unbalanced magnetron (Window and Saavides, J. Vac. Sci. Technol., A 4 (1986)). Magnetrons 208 and 210 are connected on opposite sides of AC power supply 319. Power supply 319 is an alternating current power supply with an exemplary frequency range of between 20 kHz and 6000 kHz. Power supplies with higher or lower frequencies can also be used. Each magnetron 208 and 210 produces negative glow regions NG and form a merged positive column PC.

To enhance the operating time of the process, shielding 213 is provided for PECVD apparatus 500 to direct the flow of precursor gas 251 and to thereby protect each magnetron 208 and 210 from unwanted deposition. The shielding arrangement preferably has a shield 213 that encloses or isolates magnetrons 208 and 210 such that precursor gas 251 preferentially does not interact with negative glow regions NG and deposit material onto magnetrons 208 and 210. Shield 213 includes elongate apertures 219 positioned such that the positive column PC emanating from magnetrons 208 and 210 passes through the elongate or slit-like apertures 219 toward substrate S. Shield 213 is disposed such that it is spaced apart from substrate S.

Distribution manifold 211 for precursor gas 251 is positioned such that the precursor gas 240 is injected into the PC along the length of the PC over substrate S. A vacuum pump (not shown) is provided to remove the PECVD process remnants from the deposition areas as shown at 961. The shield 213 and vacuum pump configuration are preferably designed to promote flow of the process gases through the PC before reaching the exhaust 961 so as to increase the usage efficiency of the PECVD process.

It will be apparent to those skilled in the art that different configurations of shield 213 may be provided. It will also be apparent to those skilled in the art that while a single shield box 213 is shown, each plasma source 208 and 210 are alternatively enclosed within a separate shield portion. In all of the embodiments shown and described, the various shields may comprise aluminum or similar plasma chamber construction materials.

The present invention is further detailed with respect to the following nonlimiting example. The example is only exemplary of the operation of the present invention and is not intended to limit the scope of the appended claims in any way.

Patent documents and publications mentioned in the specification are indicative of the levels of those skilled in the art to which the invention pertains. These documents and publications are incorporated herein by reference to the same extent as if each individual document or publication was specifically and individually incorporated herein by reference.

The invention has been described in terms of several embodiments. It will be apparent to those skilled in the art that various changes and modifications can be made to the embodiments without departing from the spirit or scope of the invention. It is not intended that the invention be limited by the embodiments shown and described. It is intended that the scope of the invention be limited in scope only by the claims appended hereto.

1. A plasma enhanced chemical vapor deposition apparatus for coating material onto a surface of a substrate within a process chamber, the apparatus comprising:
a plasma source disposed within the process chamber, said plasma source producing one or more negative glow regions and one or more positive columns, at least one positive column being in proximity to the substrate surface;
at least one inlet to inject a chemical vapor deposition precursor gas into the process chamber to interact with said positive column to deposit material onto the substrate surface;
at least one outlet for providing a pumped exit for gas in said process chamber;
said at least one inlet and said plasma source positioned in relationship to the substrate surface and to each other such that substantially all of said precursor gas injected into the process chamber flows into said positive column adjacent the substrate surface under conditions for coating material onto the substrate surface in preference to said plasma source.

2. The apparatus of claim 1, further comprising a manifold to channel said precursor gas to flow into said positive column.

3. The apparatus of claim 1, further comprising a shield to channel said precursor gas into said positive column and away from said negative glow regions.

4. The apparatus of claim 2, wherein said manifold has a plurality of inlets along a length of said plasma source.

5. The apparatus of claim 4, further comprising an opening disposed adjacent to said manifold to channel said precursor gas into said positive column adjacent the substrate surface.

6. The apparatus of claim 1 further comprising a system for conveying the substrate.

7. The apparatus of claim 1 wherein the substrate is flexible.

8. The apparatus of claim 1 wherein said plasma source is one of: a single rotary magnetron, a dual rotatory magnetron, a single planar magnetron or a dual planar magnetron.

9-11. (canceled)

12. The apparatus of claim 1 further comprising a second inlet to provide inert or reactive gas to said plasma source.

13. The apparatus of claim 1 wherein said plasma source is disposed such that said positive column impinges on the substrate substantially perpendicular to the substrate surface.

14. The apparatus of claim 1 wherein said plasma source is disposed such that said positive column impinges upon the substrate substantially parallel to the substrate surface.

15. The apparatus of claim 1, wherein:
said plasma source is a dual magnetron and further comprises at least one of a shield or a manifold to channel said precursor gas to flow into said positive column; and
a system for conveying the substrate.

16. A process for plasma enhanced chemical vapor deposition coating of material onto a substrate surface of a substrate, comprising:
providing a process chamber;
disposing a plasma source within said process chamber, said plasma source producing one or more negative glow regions and one or more positive columns projecting toward the substrate surface;
injecting a chemical vapor deposition precursor gas into said process chamber to interact substantially only with at least one positive column; and
depositing the material by plasma enhanced chemical vapor deposition coating onto the substrate surface of the substrate and inhibiting interaction of said gas with said negative glow regions.

17. The process of claim 16 wherein said chemical vapor deposition precursor gas is injected adjacent to the substrate surface.

18. The process of claim 16 wherein said chemical vapor deposition precursor gas is injected adjacent to the substrate surface and from opposing sides bounding said positive columns.

19. The process of claim 16 wherein the material being depositing is a metal oxide.

20. The process of claim 16 further comprising moving the substrate during said deposition.

21. The process of claim 20 wherein the substrate is moved with a conveyance system for a flexible rolled substrate.

22. The process of claim 20 wherein the substrate is moved with a conveyance system for a self-supporting planar substrate.

23. The process of claims 16 to 22 wherein depositing the material is continuous for more than 100 hours.

24. (canceled)
